(19) United States
(12) Patent Application Publication
(10) Pub. No.: US 2023/0261127 A1
(43) Pub. Date: Aug. 17, 2023

(54) FLEXIBLE MEMBRANE PROVIDED WITH PHOTOVOLTAIC CELLS

(71) Applicant: THALES, COURBEVOIE (FR)

(72) Inventors: Eric BELLOUR, CANNES LA BOCCA (FR); Frédéric MALORON, CANNES LA BOCCA (FR); Gilles GANS, CANNES LA BOCCA (FR)

(21) Appl. No.: 17/921,312

(22) PCT Filed: Apr. 27, 2021
(86) PCT No.: PCT/EP2021/060990

§ 371 Date: Oct. 25, 2022

(30) Foreign Application Priority Data
Apr. 28, 2020 (FR) 2004215

(51) Int. Cl. H01L 31/048

(52) U.S. Cl. CPC H01L 31/0481

(57) ABSTRACT

A membrane capable of passing from a configuration wound about a first axis Z to a configuration deployed along a second axis X substantially perpendicular to the first axis Z, includes a. a main substrate comprising an upper surface covered at least partially with a first layer comprising a first thermoplastic polymer, b. at least one electrically conductive track, c. a photovoltaic unit comprising a secondary substrate and at least one photovoltaic cell fixed to an upper surface of the secondary substrate, the photovoltaic unit being designed to produce an electric current, and being electrically connected to the at least one electrically conductive track, the secondary substrate comprising a lower surface, opposite the upper surface of the secondary substrate and oriented towards the upper surface of the main substrate, the lower surface of the secondary substrate being covered at least partially with a second layer comprising a second thermoplastic polymer, the lower surface of the secondary substrate of the photovoltaic unit and the upper surface of the main substrate being at least partially heat welded.

The present invention relates to a membrane equipped with photovoltaic cells. The invention applies to the field of satellites and space equipment, but may also find application in products on the ground.

The invention is described using the example of a membrane for a space solar generator, but it also applies to any other type of electrical generation involving a membrane and solar cells.

A satellite is provided with solar generators in order to supply it with electricity from solar cells exposed to solar radiation. In general, solar panels are rigid panels stowed on the body of the satellite and provided with an articulation allowing them to be deployed once in orbit. This solution is not optimal, both in terms of on-board mass (rigid panel and articulation) and power that can be fitted on board (limited size of the rigid panels) and no longer allows the imposed spatial constraints to be met. Specifically, it is desirable to have increasingly powerful solar generators in a limited volume stowed under the shroud.

One solution to this problem is to turn to a flexible membrane. The solar cells are disposed on a main substrate. The assembly (substrate and solar cells) may then be in stowed (i.e. wound) configuration during the launch phase and in deployed (i.e. unwound) configuration during operation. Since solar cells are extremely fragile, the membrane has to perform several functions. First of all, the main substrate performs a mechanical function. In the stowed configuration, the cells must be maintained and positioned in a predefined manner in order to guarantee the inter-turn center-to-center distance and to ensure immobilization avoiding impacts or movements of the cells with respect to one another. It is also necessary to take up the loads applied to the whole of the main substrate and solar cells during launch. In the deployed configuration, the cells must also be maintained and positioned in a predefined manner, in particular for the deployed surface to be flat. Lastly, the frequency of the complete wing must not be perturbed. In other words, good stiffness in the plane must be guaranteed. Another function to be provided by the membrane is the electrical function. It is necessary to ensure connections between the solar cells and then towards the base of the solar generator. A final function that the membrane must provide is the thermal function, in order to ensure good thermal regulation of the cells and to be compatible with partial shading, which is a source of very significant temperature gradients (between -100 and +100° C., or even -200 and +200° C.).

However, such a flexible membrane exhibits several disadvantages. The elements, and in particular the solar cells, are assembled on the substrate with structural adhesive, double-sided adhesive or by a mechanical fastening system using textile hooks and loops (also known under the name Velcro).

The solution using structural adhesive requires specific implementation of the adhesive and a polymerization time which ranges from 2 to 7 days. The 2-day accelerated polymerization requires placing the parts to be assembled in a heat chamber. This implementation on a complete wing of a solar generator measuring around twenty meters in length would require considerable and costly means. Polymerization in ambient air, more suited to the size of the solar generator, requires immobilization of the equipment and the storage room for 7 days.

The solution using double-sided adhesive requires a specific and complicated implementation. Even if double-sided adhesive bonding does not require polymerization time, the process is still delicate to implement and the mechanical strength of the bonding obtained is much less than that of a structural adhesive. The strength is very low in cold conditions and radiation resistance is low.

In addition, a solution based on adhesive bonding or a mechanical fastening system using textile hooks and loops thermally decouples the elements from one another and adds volume to the assembly.

The three solutions of the prior art mentioned above additionally have the disadvantage of adding mass to the elements to be assembled. Structural adhesive has a density of approximately 1000 kg/m³. The impact of the mass on a wing 20 meters in length is therefore non-negligible (of the order of 4 kg). The adhesive film has a density equivalent to that of the structural adhesive. Its impact on the mass of the wing is therefore significant.

In addition, a solution using adhesive bonding also has the disadvantage of a lack of calibration of the thickness and of the amount of adhesive applied to the assembly.

The invention aims to overcome all or some of the problems cited above by proposing a membrane of photovoltaic cells making it possible to create a solar generator that is the most powerful possible with the smallest possible volume under the shroud and smallest possible on-board mass, while performing the mechanical, electrical and thermal functions.

To this end, one subject of the invention is a membrane capable of passing from a configuration wound about a first axis Z to a configuration deployed along a second axis X substantially perpendicular to the first axis Z, the membrane comprising:
a. a main substrate comprising an upper surface covered at least partially with a first layer comprising a first thermoplastic polymer,
b. at least one electrically conductive track,
c. a photovoltaic unit comprising a secondary substrate and at least one photovoltaic cell fixed to an upper surface of the secondary substrate, the photovoltaic unit being designed to produce an electric current, and being electrically connected to the at least one electrically conductive track, the secondary substrate comprising a lower surface, opposite the upper surface of the secondary substrate and oriented towards the upper surface of the main substrate, the lower surface of the secondary substrate being covered at least partially with a second layer comprising a second thermoplastic polymer,
and the lower surface of the secondary substrate of the photovoltaic unit and the upper surface of the main substrate being at least partially heat welded.

Advantageously, the photovoltaic unit is a photovoltaic module comprising a plurality of photovoltaic cells fixed to the upper surface of the secondary substrate.

Advantageously, the main substrate may be perforated.

In one embodiment, the membrane according to the invention may further comprise at least one additional element comprising a connection surface covered at least partially with a third layer comprising a third thermoplastic polymer, said connection surface of the additional element being at least partially heat welded to the upper surface or a lower surface of the main substrate, opposite the upper surface of the main substrate, the additional element being a protective foam, a sheath for a cable, an insulator, a connector, an electrical component, a membrane stiffener, or a support loop for a membrane stiffener.

Advantageously, the main substrate may comprise reinforcing fibers, preferentially glass fibers, carbon fibers and/or aramid fibers.

Advantageously, the first thermoplastic polymer, the second thermoplastic polymer and/or the third thermoplastic polymer is a polymer from the family of the polyaryletherketone (PAEK) polymers, preferentially a polymer of polyetheretherketone (PEEK) type.

Advantageously, the first thermoplastic polymer and/or the second thermoplastic polymer and/or the third thermoplastic polymer are the same thermoplastic polymer.

The invention also relates to a satellite comprising at least one such membrane.

The invention will be better understood and further advantages will emerge on reading the detailed description of an embodiment, given by way of example, this description being illustrated by the appended drawing in which:

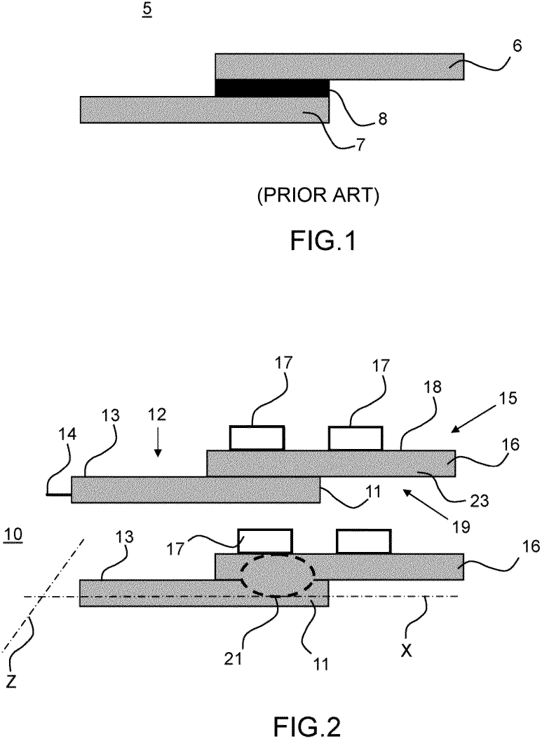

FIG. 1 schematically represents a membrane with a photovoltaic cell of the prior art;

FIG. 2 schematically represents a membrane with a photovoltaic cell according to the invention;

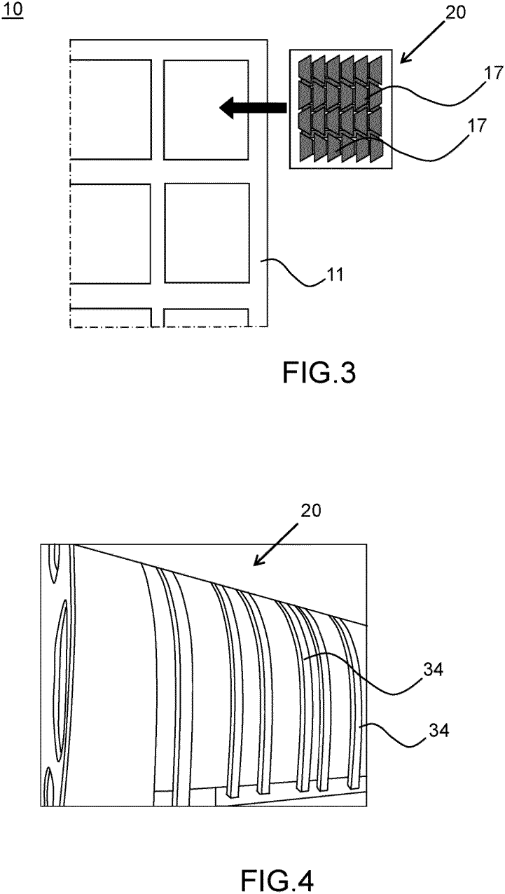

FIG. 3 schematically represents an embodiment of the membrane according to the invention;

FIG. 4 schematically represents another embodiment of the membrane according to the invention;

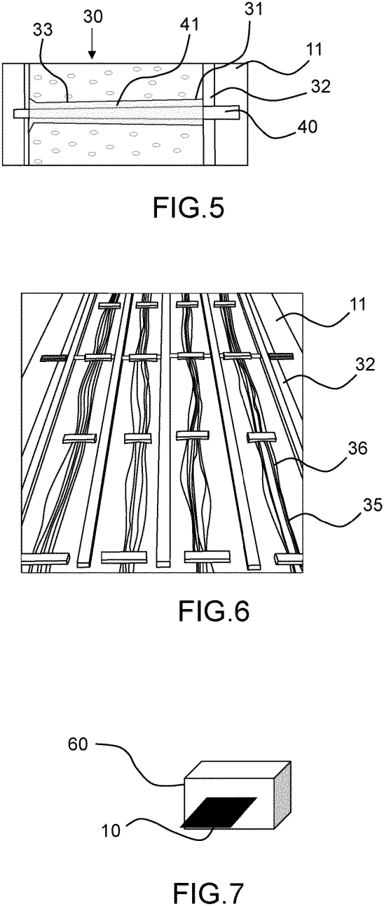

FIG. 5 schematically represents another embodiment of the membrane according to the invention;

FIG. 6 schematically represents another embodiment of the membrane according to the invention;

FIG. 7 represents a satellite equipped with at least one membrane according to the invention.

For the sake of clarity, identical elements bear the same references in the various figures. In this application, the invention is presented using the nonlimiting example of a membrane intended for a satellite. Nonetheless, the invention does not apply only to space equipment, but may also apply to any membrane with solar cells.

FIG. 1 schematically represents a membrane 5 with a photovoltaic cell 6 of the prior art. The membrane 5 comprises a substrate 7. The lower surface of the photovoltaic cell 6 is fixed to the upper surface of the substrate 7 by means of a glue, an adhesive or a Velcro-type fastening system (reference 8). The prior art therefore requires the addition of material to produce the assembly of the photovoltaic cell 6 on the substrate 7, with all of the disadvantages mentioned above.

FIG. 2 schematically represents a membrane 10 with a photovoltaic cell 17 according to the invention. The membrane 10 is capable of passing from a configuration wound around a mandrel about a first axis Z to a configuration deployed along a second axis X substantially perpendicular to the first axis Z. The mandrel is driven in rotation by a drive device, as is usual and known to a person skilled in the art. According to the invention, the membrane 10 comprises a main substrate 11 comprising an upper surface 12 covered at least partially with a first layer 13 comprising a first thermoplastic polymer. The membrane 10 comprises at least one electrically conductive track 14. The membrane 10 comprises a photovoltaic unit 15 comprising a secondary substrate 16 and at least one photovoltaic cell 17 fixed to an upper surface 18 of the secondary substrate 16. The photovoltaic unit 15 is designed to produce an electric current, and is electrically connected to the at least one electrically conductive track 14. The electrically conductive track 14 is designed to supply the satellite with electrical energy resulting from the photovoltaic unit 15.

The secondary substrate 16 comprises a lower surface 19, opposite the upper surface 18 of the secondary substrate 16 and oriented towards the upper surface 12 of the main substrate 11. The lower surface 19 of the secondary substrate 16 is covered at least partially with a second layer 23 comprising a second thermoplastic polymer.

The lower surface 19 of the secondary substrate 16 of the photovoltaic unit 15 and the upper surface 12 of the main substrate 11 are at least partially heat welded. In other words, the main substrate and the secondary substrate are fused together at the two surfaces thereof that are in contact (upper surface 12 of the main substrate 11 and lower surface 19 of the secondary substrate 16). In other words, the main substrate 11 and the secondary substrate 16 form a continuous medium. The two substrates do not exhibit any discontinuity.

The upper surface 12 may be covered partially with the first layer 13 comprising the first thermoplastic polymer or totally. Likewise, the lower surface 19 of the secondary substrate 16 may be covered partially with the second layer 23 comprising the second thermoplastic polymer or totally. The first layer 13 and the second layer 23, when they partially cover the surface, may be in the form of strips or dots, with a surface area allowing the two substrates to be heat welded together.

In addition, the secondary substrate to which the photovoltaic cell 17 is fixed may be seen as an intermediate substrate, but it may also be part of the photovoltaic cell 17. In other words, the invention applies as before with one or more photovoltaic cells 17 the rear face of which is covered at least partially with the second layer 23 comprising the second thermoplastic polymer.

The invention thus makes it possible to assemble the photovoltaic unit with the main substrate 11 without addition of material. The assembly is obtained by heat welding the parts to be assembled. Until now, the substrates used for this type of application were made of carbon, of aluminum or of imide-based polymer (also known under the name Kapton), i.e. not heat-weldable, meaning that there was no incentive to perform heat welding for the assembly of a photovoltaic unit on a substrate for a membrane.

The solution proposed by the invention is to heat weld the parts to be assembled. The process is applicable to thermoplastic materials or materials comprising at least one surface made of thermoplastic material. The assembly of the two substrates is effected by the external supply of heat. This external supply may for example be effected by means of a heating mirror: the two substrates to be assembled are positioned facing each other leaving a space in which is positioned a heating mirror which heats from both sides. The substrates are brought towards this mirror until the two layers of thermoplastic material have reached their surface melting point. When the melting points are reached, the heating mirror is removed. The two substrates are then brought into contact with each other for a few seconds, as shown at the top of FIG. 2. After a few seconds of cooling, the heat weld is produced, as shown at the bottom of FIG. 2. The two substrates now form just a single one-piece component, as can be seen at reference 21. Via zone 21, the two substrates 11, 16 are no longer separate. They are joined. The material is continuous. The assembly may also be effected by hot air or any other suitable process.

As a result, since the two substrates 11, 16 are fused together, the mechanical strength of the assembly (main substrate 11 and secondary substrate 16 with its photovoltaic unit 15) is reinforced. There is no mechanical discontinuity between the main substrate 11 and the photovoltaic unit 15, which is optimal for the functional stresses of the solar generator during the winding of the membrane 10 on its mandrel, during the deployment of the membrane 10, the passage of the substantially spherical heat-welded zone and the maintenance of the substantially spherical heat-welded zone in the partially unwound position of the membrane.

In addition, the production time for such a membrane 10 is optimal since the heat welding is quick to perform. There is no long polymerization or complex process to implement.

This solution also has the advantage of not adding assembly material, and therefore, in view of the material thicknesses employed, this represents a significant mass saving on the mass of the solar generator.

Lastly, from a thermal point of view, the assembly by heat welding also proves to be excellent for increasing the thermal conductivity between the two assembled parts, compared to a conventional assembly by adhesive bonding, film or Velcro.

By virtue of the invention, the overall thermoelastic effect on the complete wing of the solar generator is optimized with a CTE (coefficient of thermal expansion) that is homogeneous between the different parts (here the substrates 11, 16). This constitutes an improvement on the prior art in which thermoelastic effects could arise between the elements and their binder.

FIG. 3 schematically represents an embodiment of the membrane 10 according to the invention. In this embodiment, the main substrate 11 is perforated. The perforation of the main substrate 11 allows better thermal dissipation of the heat via the rear face of the photovoltaic cells.

In one embodiment, the photovoltaic unit 15 may be a photovoltaic module 20 comprising a plurality of photovoltaic cells 17 fixed to the upper surface 18 of the secondary substrate 16. In other words, the invention relates to a membrane 10 on which photovoltaic cells can be fixed to the upper surface 18 of the secondary substrate 16, itself heat-welded to the main substrate 11. Or else the photovoltaic cells may themselves comprise a thermoplastic polymer layer heat-welded to the main substrate 11. Or else the photovoltaic cells may be grouped together in the form of a photovoltaic module, itself either comprising a lower surface made of thermoplastic polymer or being fixed to a substrate with a lower surface made of thermoplastic polymer. Of course, the membrane may comprise a combination of these variants.

The invention is thus based on photovoltaic cells or photovoltaic modules assembled optionally together and on the main substrate by heat welding. As will become apparent in the remainder of the description, the invention is also directed to attaching, to the main substrate and/or to the photovoltaic unit, other additional elements on the same heat welding principle, such as for example membrane stiffeners, loops, cabling supports, connectors, etc. The assembly therefore constitutes a complete solar generator wing that may be of very large dimensions, without using additional assembly material.

In addition to the advantages already mentioned, the invention makes it possible to avoid electrical discontinuities in the case of antistatic photovoltaic modules. There is increased thermal conductivity between the different substrates. It is also possible to note a reduction in the level of pollution, since there is no outgassing of the adhesives. Thus, there is no contamination of the elements that are situated in the field of view of the on-board instruments. In addition, the assembly of the invention provides insensitivity to radiation compared to traditional adhesive bonding. As explained below, the invention also simplifies repairs in the event of malfunction of an element of the membrane.

The solution provides a gain in the overall mechanical performance of the wing by eliminating the mechanical discontinuity between the main substrate and the photovoltaic modules, or else among the photovoltaic modules themselves. The solution provides a thermal benefit due to the material continuity between the assembled elements. This conductive aspect is very important in the case for example of a photovoltaic module on a solid (non-perforated) substrate, where the heat exchange between the front face and the rear face of the module is vital. This increased thermal conductivity proves to be beneficial for the electrical performance of the wing. By reducing the operating temperature of the photovoltaic cells, their efficiency is increased. This means that, with the same number of photovoltaic cells, the solar generator has better electrical performance, or, for the same power delivered, the generator will be less expensive with fewer cells. This results in a saving in volume and mass.

Better conductive thermal coupling between the elements makes it possible to increase the rejection capacity for highly dissipating elements such as diodes and power cables.

Specifically, as described below, the membrane 10 according to the invention may further comprise at least one additional element 30 comprising a connection surface 31 covered at least partially with a third layer 33 comprising a third thermoplastic polymer, said connection surface 31 of the additional element 30 being at least partially heat welded to the upper surface 12 or a lower surface 32 of the main substrate 11, opposite the upper surface 12 of the main substrate 11, the additional element 30 being a protective foam 34, a sheath 35 for a cable 36, an insulator, a connector, an electrical component, a membrane stiffener, or a support loop 41 for a membrane stiffener.

FIG. 4 schematically represents another embodiment of the membrane according to the invention. In this embodiment, the membrane comprises a protective foam 34. The protective foam comprises a connection surface covered at least partially with a thermoplastic polymer layer. The foam 34 is preferentially heat welded to the lower surface of the main substrate 11 so as to protect, in the wound configuration of the membrane 10, the photovoltaic cells of the lower turn of the wound membrane. Alternatively, the foam 34 may be heat welded to the lower face of the secondary substrate, or to the upper surfaces of the substrate 11, 16, at locations making it possible to prevent possible impacts between the cells and/or the additional elements when the membrane is wound.

The entirety of the foams used may represent large bonding surfaces. The heat welding of the foam to the substrate allows a saving in mass of the membrane.

FIG. 5 schematically represents another embodiment of the membrane according to the invention. In this embodiment, the membrane comprises a support loop 41 for a membrane stiffener. The support loop 41 comprises a connection surface covered at least partially with a thermoplastic polymer layer. The support loop 41 is preferentially heat welded to the lower surface of the main substrate 11 so as to ensure material continuity for better mechanical performance as explained above. A stiffener may then be slid into the support loop 41 to provide better stiffness to the membrane 10.

Alternatively, the membrane stiffener may comprise a connection surface covered at least partially with a thermoplastic polymer layer and the stiffener may then be directly heat welded to the main substrate 11.

The invention also applies with a main substrate 11 comprising reinforcing fibers, preferentially glass fibers, carbon fibers and/or aramid fibers. These reinforcing fibers are preferentially in the main substrate 11.

FIG. 6 schematically represents another embodiment of the membrane according to the invention. In this embodiment, the membrane comprises a sheath 35 for a cable 36. The sheath 35 comprises a connection surface covered at least partially with a thermoplastic polymer layer. The sheath 35 is preferentially heat welded to the lower surface of the main substrate 11 so as to ensure material continuity as explained above. The sheath 35 may also be heat welded to the upper surface of the main substrate 11, close to the photovoltaic cells. The cable 36 is positioned in the sheath 35. The cable 36 may also comprise a connection surface covered at least partially with a thermoplastic polymer layer and the cable 36 may then be directly heat welded to the main substrate 11.

The same principle applies with any other additional element which may be used on the membrane 10, for example an insulator, a connector, an electrical component such as a thermistor, a diode or a diode board.

Lastly, the solution provided by the invention provides the advantage of simplifying replacement and/or repair of a defective or damaged element, whether this be a photovoltaic cell or one of the additional elements mentioned above. All of these elements, if they are defective, can be replaced with a non-defective element without the risk of delamination or damage to the substrate or photovoltaic module on which they are attached.

In order to do this, it suffices to locally apply an external supply of heat near to the element to be replaced. Once the melting point of the thermoplastic has been reached, the defective element is detached from its substrate and a non-defective element is attached there by performing the same heat-welding process. Consequently, even after a repair, the same mechanical, electrical and thermal performance levels are ensured as in the initial case.

Advantageously, the first thermoplastic polymer, the second thermoplastic polymer and/or the third thermoplastic polymer is a polymer from the family of the polyaryletherketone (PAEK) polymers, preferentially a polymer of polyetheretherketone (PEEK) type.

Advantageously, the first thermoplastic polymer and/or the second thermoplastic polymer and/or the third thermoplastic polymer are the same thermoplastic polymer. This facilitates the performance of the heat welding since the melting point to be achieved is the same. The insertion and the removal of the heating mirror between the surfaces to be fused can therefore be more easily controlled.

FIG. 7 represents a satellite equipped with at least one membrane according to the invention.

1. A membrane capable of passing from a configuration wound around a mandrel about a first axis Z to a configuration deployed along a second axis X substantially perpendicular to the first axis Z, comprising:
a. a main substrate comprising an upper surface covered at least partially with a first layer comprising a first thermoplastic polymer,
b. at least one electrically conductive track,
c. a photovoltaic unit comprising a secondary substrate and at least one photovoltaic cell fixed to an upper surface of the secondary substrate, the photovoltaic unit being designed to produce an electric current, and being electrically connected to the at least one electrically conductive track, the secondary substrate comprising a lower surface, opposite the upper surface of the secondary substrate and oriented towards the upper surface of the main substrate, the lower surface of the secondary substrate being covered at least partially with a second layer comprising a second thermoplastic polymer,
and in that the lower surface of the secondary substrate of the photovoltaic unit and the upper surface of the main substrate are at least partially heat welded, without mechanical discontinuity between the main substrate and the photovoltaic unit.

2. The membrane as claimed in claim 1, wherein the photovoltaic unit is a photovoltaic module comprising a plurality of photovoltaic cells fixed to the upper surface of the secondary substrate.

3. The membrane as claimed in claim 1, wherein the main substrate is perforated.

4. The membrane as claimed in claim 1, further comprising at least one additional element comprising a connection surface covered at least partially with a third layer comprising a third thermoplastic polymer, said connection surface of the additional element being at least partially heat welded to the upper surface or a lower surface of the main substrate, opposite the upper surface of the main substrate, the additional element being a protective foam, a sheath for a cable, an insulator, a connector, an electrical component, a membrane stiffener, or a support loop for a membrane stiffener.

5. The membrane as claimed in claim 1, wherein the main substrate comprises reinforcing fibers, preferentially glass fibers, carbon fibers and/or aramid fibers.

6. The membrane as claimed in claim 4, wherein the first thermoplastic polymer, the second thermoplastic polymer and/or the third thermoplastic polymer is a polymer from the family of the polyaryletherketone (PAEK) polymers, preferentially a polymer of polyetheretherketone (PEEK) type.

7. The membrane as claimed in claim 4, wherein the first thermoplastic polymer and/or the second thermoplastic polymer and/or the third thermoplastic polymer are the same thermoplastic polymer.

8. A satellite comprising at least one membrane as claimed in claim 1.
